(19) United States
(12) Patent Application Publication
(10) Pub. No.: US 2013/0112471 A1
(43) Pub. Date: May 9, 2013

(54) PRINTED CIRCUIT BOARD AND METHOD OF MANUFACTURING THE SAME

(71) Applicants: Sung Nam CHO, Gyunggi-do (KR); Jun Young KIM, Seoul (KR)

(72) Inventors: Sung Nam CHO, Gyunggi-do (KR); Jun Young KIM, Seoul (KR)

(73) Assignee: SAMSUNG ELECTRO-MECHANICS CO., LTD., Gyunggi-do (KR)

(21) Appl. No.: 13/353,157

(22) Filed: Jan. 18, 2012

(30) Foreign Application Priority Data
Nov. 7, 2011 (KR) 10-2011-0115322

(51) Int. Cl. H05K 1/11; H05K 3/12

(52) U.S. Cl. 174/266; 427/98.4; 427/553

(57) ABSTRACT

Disclosed herein is a printed circuit board and a method of manufacturing the same. The printed circuit board includes preparing a base substrate; forming a pattern layer for forming via holes on the base substrate by printing ink for forming via holes; forming an insulating layer on the base substrate including the pattern layer for forming via holes; and removing the pattern layer for forming via holes.

### CROSS REFERENCE TO RELATED APPLICATION

This application claims the benefit of Korean Patent Application No. 10-2011-0115322, filed on Nov. 7, 2011, entitled “Printed Circuit Board and Method of Manufacturing the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

With the development of a smart device, the price of the smart device is rapidly reducing. Meanwhile, a demand for a high-performance and low-cost multilayer substrate that is core components of the device has been increased.

Via holes on the multilayer substrate serve as inter-layer conduction.

Generally, the via holes are processed using CO₂ laser. However, the number of via holes are suddenly increased with the development of the smart devices such that the weight of processing cost of the via holes has been gradually increased in the substrate.

Therefore, there is a need to reduce a manufacturing process procedure and cost of the via holes.

Describing in more detail, as disclosed in Document 1, the via holes are processed using a laser drill.

The method for processing a laser drill as described above is sorted into CO₂ laser, UV (YAG) laser according to an output wavelength of laser.

Among others, the current mass production process forms a plated through hole (PTH) and a blind via hole (BVH) less than 100 μm by using the CO₂ laser.

The CO₂ laser drill may have high output and productivity and the maintenance cost thereof may be reduced. For this reason, the CO₂ laser drill is generally used to form the via holes of 50 μm or more.

On the other hand, it is impossible to form fine via holes less than 50 μm and it is difficult to process copper.

Meanwhile, a method for processing UV laser may process fine via holes less than 50 μm and copper, but the maintenance cost thereof may be high.
[Document 1] KR 10-0674316 B 2007. 1. 18

### SUMMARY OF THE INVENTION

The present invention has been made in an effort to provide a printed circuit board with the reduced process procedure and costs for processing via holes and a method of manufacturing the same.

According to a preferred embodiment of the present invention, there is provided a method of manufacturing a printed circuit board, including: preparing a base substrate; forming a pattern layer for forming via holes on the base substrate by printing ink for forming via holes; forming an insulating layer on the base substrate including the pattern layer for forming via holes; and removing the pattern layer for forming via holes.

At the forming of the pattern layer for forming via holes, the ink for forming via holes may be made of a wax material.

At the forming of the pattern layer for forming via holes, the printing of the ink for forming via holes may be performed by discharging ink in a drop on demand (DOD) manner.

The forming of the pattern layer for forming via holes may include curing the pattern layer for forming via holes.

The pattern layer for forming via holes may be cured through ultraviolet irradiation.

The forming of the pattern layer for forming via holes may include discharging the ink for forming via holes in a drop on demand (DOD) manner, curing the ink while discharging the ink, or seating the ink on the base substrate and then, curing the ink.

The removing of the pattern layer for forming via holes may remove the pattern layer for forming via holes through a postcure process or a desmear process.

At the forming of the insulating layer, a height of the insulating layer may be formed higher than a height of the pattern layer for forming via holes based on a thickness direction of the printed circuit board.

According to another preferred embodiment of the present invention, there is provided a printed circuit board, including: a base substrate; and an insulating layer having via opening part on the base substrate, wherein a side wall of the via opening part is in a ruggedly curved form.

The via opening part may be formed by discharging the ink for forming via holes in a drop on demand (DOD) manner.

### BRIEF DESCRIPTION OF THE DRAWINGS

FIG. 1 is a diagram showing a configuration of a printed circuit board according to a preferred embodiment of the present invention.

FIGS. 2 to 5 are cross-sectional views sequentially showing the process of manufacturing the printed circuit board of FIG. 1.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

Printed Circuit Board

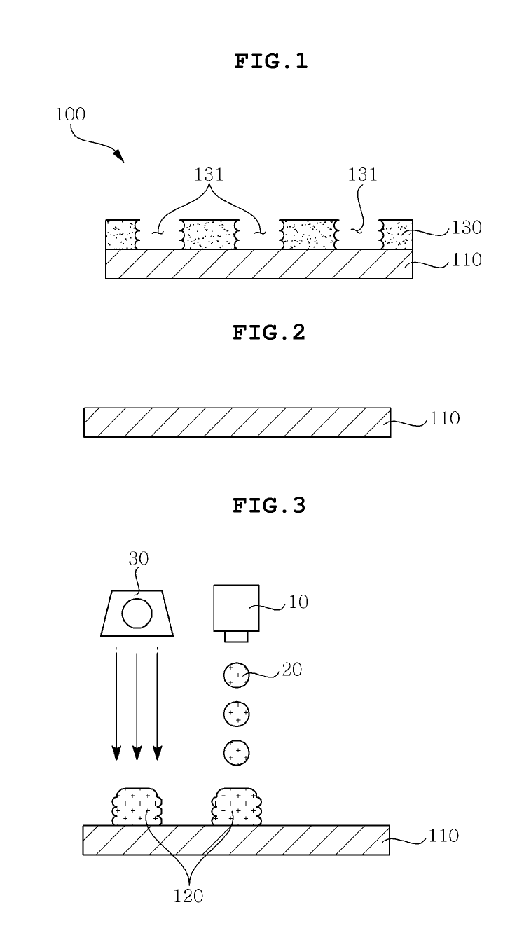

FIG. 1 is a diagram showing a configuration of a printed circuit board according to a preferred embodiment of the present invention.

As shown in FIG. 1, a printed circuit board 100 may be configured to include a base substrate 110 and an insulating layer 130 having a via opening part 131 formed on a base substrate 110.

In addition, the via opening part 131 may be formed by discharging ink for forming via holes in a drop on demand (DOD) manner.

Herein, a side wall of the via opening part 131 may be formed in a ruggedly curved form.

Describing in more detail, the via opening part 131 is formed by forming a pattern layer 120 for forming via holes by discharging ink for forming via holes by the DOD manner, forming the insulating layer 130, and then removing the pattern layer 120 for forming via holes.

As a result, the side wall of the via opening part 131 is formed in the ruggedly curved form along a shape of ink discharged several times.

In this case, since the side wall of the via opening part 131 is formed in a ruggedly curved form, the ruggedly curved form performs a roughness role, such that an adhesion between the via (not shown) and the insulating layer 130 that are formed later may be improved.

Method of Manufacturing Printed Circuit Board

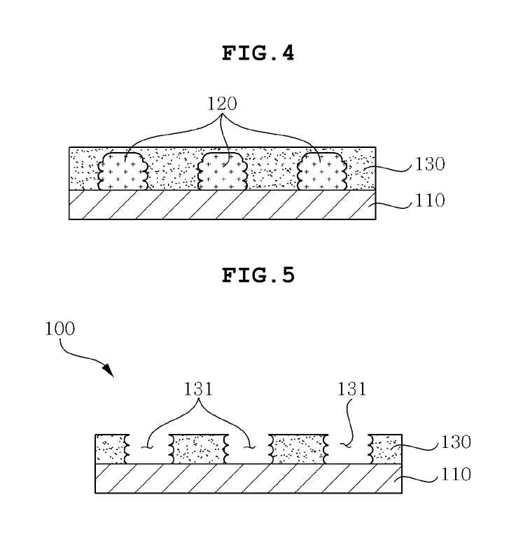

FIGS. 2 to 5 are cross-sectional views sequentially showing the process of manufacturing the printed circuit board of FIG. 1.

First, as shown in FIG. 2, the base substrate 110 may be prepared.

The base substrate 110, which is a circuit board in which the insulating layer is formed with at least one inner layer circuit, may be a printed circuit board. FIG. 2 does not show a detailed configuration of the inner layer circuit for convenience of explanation but those skilled in the art may sufficiently recognize that a general circuit board in which a circuit of at least one layer is formed on the insulating layer may be applied as the base substrate 110.

As the insulating layer, a resin insulating layer may be used. As the resin insulating layer, a thermosetting resin such as an epoxy resin, a thermoplastic resin such as polyimide, a resin having a reinforcing material such as glass fiber or inorganic filler impregnated therein, for example, prepreg, a photocurable resin, or the like, may be used, but a material of the resin insulating layer is not limited thereto.

Next, as shown in FIG. 3, the pattern layer 120 for forming via holes may be formed on the base substrate 110 by printing ink 20 for forming via holes.

Here, the ink 20 for forming via holes may be made of a wax material.

Further, the ink 20 for forming via holes may be printed by discharging the ink 20 in the drop on demand (DOD) manner.

For example, as shown in FIG. 3, the ink 20 for forming via holes is discharged through an inkjet head 10 and the discharged amount of the ink 20 is controlled in consideration of a via size to be formed later.

Here, as shown in FIG. 3, both sides of the pattern layer 120 for forming via holes may be formed in a ruggedly curved form. The reason is that the pattern layer 120 for forming via holes is formed by discharging ink in the DOD manner.

Further, when the pattern layer 120 for forming via holes is formed by printing the ink for forming via holes on the base substrate 110, the method may further include curing the pattern layer 120 for forming via holes.

In this case, the pattern layers 120 for forming via holes may be cured through an ultraviolet irradiation.

For example, as shown in FIG. 3, the ink 20 for forming via holes is discharged through the inkjet head 10 and then, is cured by using an ultraviolet irradiator 30.

Meanwhile, the forming of the pattern layer 120 for forming via holes may further include discharging the ink 20 for forming via holes in the drop on demand (DOD) manner and curing the ink 20 as soon as the ink 20 is discharged and may further include seating the ink 20 on the base substrate 110 and then, curing the ink 20.

That is, the method may cure the pattern layer 120 for forming via holes, discharging or curing the ink 20 for forming via holes, and seating and then curing the discharged ink on the base substrate 110, but is not limited thereto.

Next, as shown in FIG. 4, the insulating layer 130 may be formed on the base substrate 110 including the pattern layer 120 for forming via holes.

In this case, a height of the insulating layer 130 may be formed higher than the height of the pattern layer 120 for forming via holes based on a thickness direction of the printed circuit board 100.

This is to previously prevent the pattern layer 120 for via holes in the state in which the ink 20 for forming via holes are discharged from collapsing.

Further, as the insulating layer, the resin insulating layer may be used. As the resin insulating layer, a thermosetting resin such as an epoxy resin, a thermoplastic resin such as polyimide, a resin having a reinforcing material such as glass fiber or inorganic filler impregnated therein, for example, prepreg, a photocurable resin, or the like, may be used, but the material of the resin insulating layer is not limited thereto.

Next, as shown in FIG. 5, the pattern layer 120 for forming via holes may be removed.

In this case, the pattern layer 120 for forming via holes may be removed through a postcure process or a desmear process.

In this case, the above-mentioned postcure process or desmear process may be generally performed after the insulating layer 130 is formed, rather than a separate process to remove the pattern layer 120 for forming via holes.

As a result, since the developing process generally performed at the time of forming the via holes may be omitted, the process of forming the via holes and the manufacturing process of the printed circuit board may be simplified and the eco-friendly method may be applied by removing the environmental pollution problem due to the developing process.

In addition, as shown in FIG. 5, the side wall of the via opening part 131 in the state in which the pattern layer 120 for forming via holes is removed may be formed in the ruggedly curved form.

In this case, since the side wall of the via opening part 131 is formed in a ruggedly curved form, the ruggedly curved form performs the roughness role, such that the adhesion with the vias (not shown) that are formed later may be improved.

In addition, since the preferred embodiment of the present invention forms the pattern for forming via holes through the wax type ink, the defects due to the residual resin cannot be caused on the bottom surface of the via holes 131 even after removing the pattern layer for forming the via holes.

In addition, since the preferred embodiment of the present invention forms the pattern for forming via holes by discharging the wax type ink in the DOD manner, the uniformity of the via holes can be very excellent.

Describing in more detail, since the inkjet head 10 discharges the predetermined amount of ink in consideration of the size of the via, the pattern for forming via holes is uniform and thus, the size of the via holes to be formed later is also uniform.

As set forth above, the printed circuit board and the method of manufacturing the same according to the preferred embodiments of the present invention can reduce the process procedure and the processing costs by omitting the mask manufacturing process since the patterns for processing the vias are formed by discharging the wax type ink in the drop on demand (DOD) manner.

In addition, the printed circuit board and the method of manufacturing the same according to the preferred embodiments of the present invention can simplify the process procedure by omitting the developing process at the time of forming the vias and process the via holes by the eco-friendly method since the patterns for processing the vias are formed by discharging the wax type ink in the drop on demand (DOD) manner.

Further, the printed circuit board and the method of manufacturing the same according to the preferred embodiments of the present invention can reduce the process costs since the separate equipment for processing the via holes in addition to the CO₂ laser equipment are not required.

Moreover, the printed circuit board and the method of manufacturing the same according to the preferred embodiments of the present invention can shorten the process procedure time by omitting the mask film matching procedure or the CO₂ laser processing procedure for forming the via holes.

Although the preferred embodiments of the present invention have been disclosed for illustrative purposes, they are for specifically explaining the present invention. Therefore, a printed circuit board and a method of manufacturing the same according to the preferred embodiments of the present invention are not limited thereto, but those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention could be defined by accompanying claims.

What is claimed is:

1. A method of manufacturing a printed circuit board, comprising:
preparing a base substrate;
forming a pattern layer for forming via holes on the base substrate by printing ink for forming via holes;
forming an insulating layer on the base substrate including the pattern layer for forming via holes; and
removing the pattern layer for forming via holes.

2. The method as set forth in claim 1, wherein at the forming of the pattern layer for forming via holes, the ink for forming via holes is made of a wax material.

3. The method as set forth in claim 1, wherein at the forming of the pattern layer for forming via holes, the printing of the ink for forming via holes is performed by discharging ink in a drop on demand (DOD) manner.

4. The method as set forth in claim 1, wherein the forming of the pattern layer for forming via holes includes curing the pattern layer for forming via holes.

5. The method as set forth in claim 4, wherein the pattern layer for forming via holes is cured through ultraviolet irradiation.

6. The method as set forth in claim 1, wherein the forming of the pattern layer for forming via holes includes discharging the ink for forming via holes in a drop on demand (DOD) manner, curing the ink while discharging the ink, or seating the ink on the base substrate and then, curing the ink.

7. The method as set forth in claim 1, wherein the removing of the pattern layer for forming via holes removes the pattern layer for forming via holes through a postcure process or a desmear process.

8. The method as set forth in claim 1, wherein at the forming of the insulating layer, a height of the insulating layer is formed higher than a height of pattern layer for forming via holes based on a thickness direction of the printed circuit board.

9. A printed circuit board, comprising:
a base substrate; and
an insulating layer having via opening part formed on the base substrate, wherein a side wall of the via opening part is in a ruggedly curved form.

10. The printed circuit board as set forth in claim 9, wherein the via opening part is formed by discharging the ink for forming via holes in a drop on demand (DOD) manner.
